(19) United States
(12) Patent Application Publication
(10) Pub. No.: US 2015/0130476 A1
(43) Pub. Date: May 14, 2015

(54) DIRECT-CURRENT REGULATOR, DC-DC CONVERTER, AND METHOD FOR MONITORING ANOMALY OF DIRECT-CURRENT REGULATOR

(71) Applicant: FUJITSU LIMITED, Kawasaki-shi (JP)

(72) Inventors: Yoshimasa TAKAHASHI, Nagano (JP); Yuji UCHIYAMA, Fuji (JP)

(73) Assignee: FUJITSU LIMITED, Kawasaki-shi (JP)

(21) Appl. No.: 14/496,310

(22) Filed: Sep. 25, 2014

(30) Foreign Application Priority Data
Nov. 14, 2013 (JP) 2013-236038

(51) Int. Cl. H02M 3/158; G01R 31/02

(52) U.S. Cl. CPC H02M 3/158; G01R 31/02
USPC 324/537; 323/271

(57) ABSTRACT

A direct-current regulator includes: a fuse, a high-side switch, and a low-side switch connected in series between a high potential side input voltage terminal and a low potential side input voltage terminal; and a control unit configured to control the high-side switch and the low-side switch, wherein the fuse is formed on a silicon substrate on which the high-side switch is formed, and the fuse includes: two electrodes separately formed on the silicon substrate; a plurality of band-shaped polysilicon films formed between the two electrodes; and a linking part of a polysilicon film provided so as to connect the neighboring band-shaped polysilicon films at intermediate portions.

### CROSS-REFERENCE TO RELATED APPLICATION

This application is based upon and claims the benefit of priority of the prior Japanese Patent Application No. 2013-236038, filed on Nov. 14, 2013, the entire contents of which are incorporated herein by reference.

### FIELD

The present invention relates to a direct-current regulator and a DC-DC converter.

### BACKGROUND

The direct-current regulator has a high-side switching element between one of input terminals (high potential side) and an output terminal and a low-side switching element between the other input terminal (low potential side) and the output terminal, and carries out voltage conversion. In the direct-current regulator, a measurement circuit configured to control the switching elements and to measure temperatures, voltages, etc., is incorporated. The measurement circuit generates an anomaly detection signal when detecting anomalies of the switching elements or input/output voltage and current and sends the anomaly detection signal to the control circuit. The control circuit having received this signal performs control so as to prevent the anomalous state from continuing by stopping the operation of the regulator itself.

When the switching element enters a closed state due to the occurrence of a short circuit caused by a failure of the switching element or due to a failure of the control circuit, a large current flows between the input voltage terminal and the ground. At this time, if the measurement circuit inside the element operates and the anomaly can be detected and the operation of the direct-current regulator can be stopped, the failure does not affect the external periphery, and therefore, there is no problem.

However, in cases where failures are as (1) to (3) below, it is not possible to stop the operation of the direct-current regulator in which a failure has occurred, and therefore, the failure will affect the peripheral circuits.

(1) In the case where the input voltage and the control circuit power source short-circuit within the gate driver and the voltage for the measurement circuit and the control circuit is lost.

(2) In the case where heat is produced rapidly at the time of the failure of the switching element and the failure of the control circuit is induced before the direct-current regulator starts the operation when an anomaly occurs and the operation is no longer possible.

(3) In the case where the control unit fails and the two switching elements enter the closed state at the same time during the operation of the direct-current regulator.

The change in the characteristics with the passage of time of the switching element is not monitored previously, and therefore, in many cases, an anomaly is detected after the switching element has entered the broken state.

### RELATED DOCUMENTS

[Patent Document 1] Japanese Laid Open Patent Document No. 2009-267371
[Patent Document 2] Japanese Laid Open Patent Document No. 2010-186639
[Patent Document 3] Japanese Laid Open Patent Document No. 2010-246190
[Patent Document 4] Japanese Laid Open Patent Document No. 2002-027737

### SUMMARY

According to a first aspect, a direct-current regulator includes: a fuse, a high-side switch, and a low-side switch connected in series between a high potential side input voltage terminal and a low potential side input voltage terminal; and a control unit configured to control the high-side switch and the low-side switch, wherein the fuse is formed on a silicon substrate on which the high-side switch is formed.

According to a second aspect, a DC-DC converter includes: a regulator including: a fuse, a high-side switch, and a low-side switch connected in series between a high potential side input voltage terminal and a low potential side input voltage terminal, the fuse being formed on a silicon substrate on which the high-side switch is formed; and a control unit configured to control the high-side switch and the low-side switch; and a low-pass filter connected between a connection node of a high-side switch and a low-side switch and a low potential side input voltage terminal.

According to a third aspect, an anomaly monitoring method of a direct-current regulator, the direct-current regulator including: a fuse, a high-side switch, and a low-side switch connected in series between a high potential side input voltage terminal and a low potential side input voltage terminal, the fuse being formed on a silicon substrate on which the high-side switch is formed; and a control unit configured to control the high-side switch and the low-side switch, the method includes: controlling the high-side switch and the low-side switch so that both the switches are not brought into conduction simultaneously but brought into conduction alternately; and detecting an input current by using the fuse when controlling the high-side switch and the low-side switch so as to be brought out of conduction, and determining that the high-side switch has deteriorated when the detected input current exceeds a normal value.

According to a fourth aspect, an anomaly monitoring method of a direct-current regulator, the direct-current regulator including: a fuse, a high-side switch, and a low-side switch connected in series between a high potential side input voltage terminal and a low potential side input voltage terminal, the fuse being formed on a silicon substrate on which the high-side switch is formed; and a control unit configured to control the high-side switch and the low-side switch, the method includes: controlling the high-side switch and the low-side switch so that both the switches are not brought into conduction simultaneously but brought into conduction alternately; and detecting an input current by using the fuse after bringing the high-side switch into conduction in the state where the low-side switch is brought out of conduction, and determining that the low-side switch has deteriorated when the detected input current exceeds a normal value.

The object and advantages of the embodiments will be realized and attained by means of the elements and combination particularly pointed out in the claims.

It is to be understood that both the foregoing general description and the following detailed description are exemplary and explanatory and are not restrictive of the invention.

### BRIEF DESCRIPTION OF THE DRAWINGS

FIG. 1 is a diagram illustrating a configuration of a general direct-current regulator and an electric circuit using the direct-current regulator;

FIG. 2 is a diagram illustrating a circuit configuration of a portion for monitoring an input current;

FIG. 3 is a diagram illustrating a configuration of the direct-current regulator of the embodiment and an electric circuit that uses the direct-current regulator;

FIG. 4 is a diagram illustrating a configuration example of the fuse and the high-side switch (switching element);

FIG. 5A to FIG. 5C are diagrams illustrating a modified example of the fuse, in which FIG. 5A illustrates a fuse pattern, FIG. 5B illustrates a circuit, and FIG. 5C is a diagram for explaining a reduction in the melting time;

FIG. 6 is a diagram illustrating a modified example of the fuse whose current capacity is made variable and the high-side switch (switching element);

FIG. 7 is a diagram illustrating a configuration of a control portion that performs the function capable of varying the fuse capacity and the function to immediately stop the operation to be provided within the control circuit;

FIG. 8 is a time chart illustrating the operation of the fuse by the control portion in FIG. 7;

FIG. 9 is a diagram illustrating a circuit configuration of a portion for monitoring an input current in the direct-current regulator of the embodiment;

FIG. 10 is a diagram illustrating the above-described determination operation in the F1 current determination unit; and

FIG. 11 is a flowchart illustrating the anomalous current monitoring processing in the control circuit.

### DESCRIPTION OF EMBODIMENTS

Before explaining an embodiment, a general direct-current regulator will be explained.

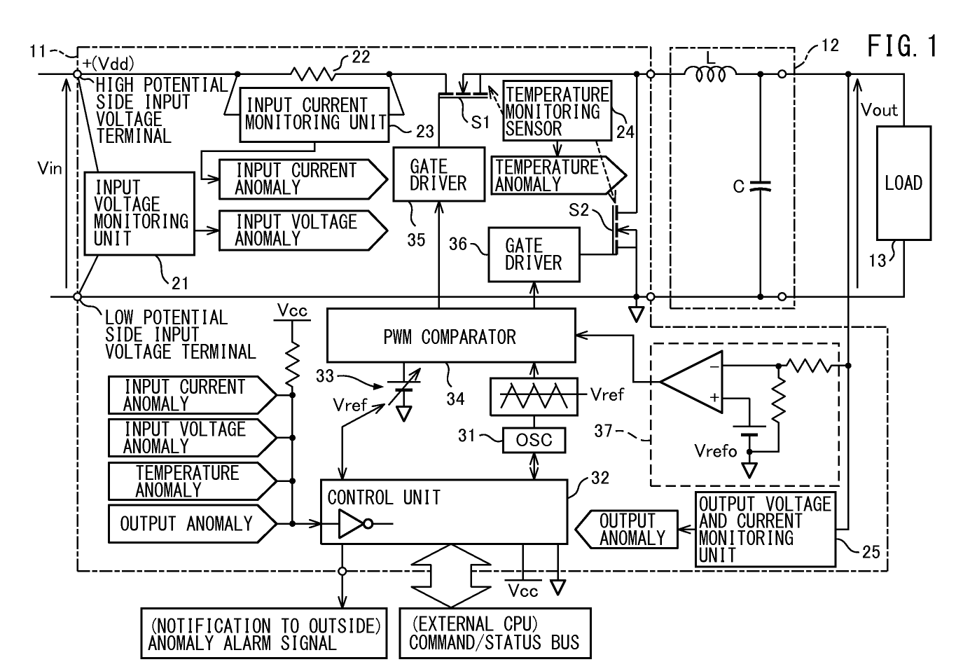

FIG. 1 is a diagram illustrating a configuration of a general direct-current regulator and an electric circuit using the direct-current regulator.

The electric circuit has a direct-current regulator 11, a low-pass filter 12, and a load 13. The direct-current regulator 11 converts the voltage of power from a direct-current power source having an input voltage Vin (e.g., 12 V) and outputs the voltage to the low-pass filter 12. As illustrated in FIG. 1, the low-pass filter 12 has an inductance element L and a capacitor C and averages an output pulse string output from the direct-current regulator 11 and outputs direct-current power having an output voltage Vout (e.g., 1 V) to the load 13. The load 13 is, for example, an electronic circuit including a CPU etc. The low-pass filter 12 is widely known, and therefore, explanation is omitted.

The direct-current regulator 11 has a high-side switch S1, a low-side switch S2, an oscillation circuit 31, a control circuit 32, a reference voltage source 33, a PWM comparator 34, a gate driver 35, a gate driver 36, and an error detection circuit 37. The direct-current regulator 11 further has an input voltage monitoring unit 21, an input current monitoring resistor 22, an input current monitoring unit 23, a temperature monitoring sensor 24, and an output voltage and current monitoring unit 25.

The high-side switch S1 and the low-side switch S2 are formed by, for example, a switching element, such as a power MOSFET. The oscillation circuit (OSC) 31 outputs a sawtooth waveform signal. The PWM comparator 34 compares the sawtooth waveform signal and a reference voltage Vref output from the reference voltage source 33 and outputs a signal to turn on S1 to the gate driver 35 in the case where Vref is exceeded. The PWM comparator 34 outputs a signal to appropriately turn on S2 during the period of time during which S1 is off to the gate driver 36. This drive signal is called a PWM (Pulse Width Modulation) signal. The gate driver 35 and the gate driver 36 drive S1 and S2 so that they do not turn on at the same time in accordance with the PWM signal. Due to this, the output pulse string is supplied from the direct-current regulator 11 to the low-pass filter 12 and the capacitor C of the low-pass filter 12 is charged. As illustrated in FIG. 1, the error detection circuit 37 has an amplifier circuit that uses an operational amplifier, and detects an error between the output voltage of the low-pass filter 12 and a target voltage Vrefo and outputs an error signal to the PWM comparator 34. The PWM comparator 34 changes the relationship between the sawtooth waveform signal and the reference voltage Vref in accordance with the error signal and changes the on/off ratio of the PWM signal. Specifically, the PWM comparator 34 lengthens the period of time during which S1 is on and shortens the period of time during which S2 is on when the output voltage of the low-pass filter 12 is lower than the target voltage, and shortens the period of time during which S1 is on and lengthens the period of time during which S2 is on when the output voltage of the low-pass filter 12 is higher than the target voltage. The operation of the direct-current regulator by the PWM control is widely known, and therefore, further explanation is omitted.

In the direct-current regulator in FIG. 1, the measurement circuit configured to measure the input/output voltage and current, the temperature of the switches S1 and S2, etc., is incorporated. The input voltage monitoring unit 21 detects the input voltage Vin and in the case where the detected voltage is beyond a predetermined voltage range, outputs an input voltage anomaly signal. The input current monitoring resistor 22 is provided in the path between the high-side input voltage terminal and S1. The input current monitoring unit 23 detects the input current by detecting the voltage across both ends of the input current monitoring resistor 22 and in the case where the detected input current is beyond a predetermined current range, outputs an input current anomaly signal. The temperature monitoring sensor 24 detects the temperatures of S1 and S2 and in the case where the detected temperatures are beyond a predetermined temperature range, outputs a temperature anomaly signal. The output voltage and current monitoring unit 25 detects the output voltage and the output current of the low-pass filter 12 and in the case where the detected output voltage and output current are beyond a predetermined range, outputs an output anomaly signal. The output current detection resistor is not illustrated schematically. In FIG. 1, the example is explained, in which monitoring of the input voltage and current, monitoring of the temperatures of S1 and S2, and monitoring of the output voltage and current are performed, but in general, the measurement function to be implemented is determined by taking the balance between the circuit scale of the measurement circuit and the cost of the direct-current regulator.

The control circuit 32 is formed by, for example, the CMOS logic and connected to an external CPU via a command/status bus. The control circuit 32 receives the input voltage anomaly signal, the input current anomaly signal, the temperature anomaly signal, and the output anomaly signal and controls the reference voltage source 33 and the oscillation circuit 31 in accordance with the command from the outside. The control unit 32 outputs the control state to the command/status bus and at the same time, outputs an anomaly alarm signal to the outside at the time of occurrence of an anomaly. Although not illustrated schematically, it is possible for the control unit 32 to bring S1 and S2 into the off state by controlling the gate drivers 35 and 36 via the PWM comparator 34 or without interposing the PWM comparator 34. Upon receipt of the above-described anomaly detection signal, the control unit 32 performs control so as to prevent the anomalous state from continuing by stopping the operation of the direct-current regulator 11 itself by controlling the operation of S1 and S2 in accordance with the signal.

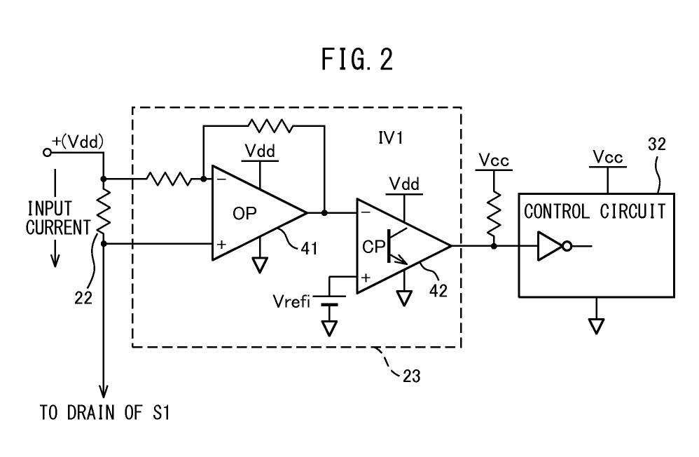

FIG. 2 is a diagram illustrating a circuit configuration of a portion for monitoring an input current.

The input current monitoring unit 23 has an operational amplifier 41, a comparator 42, a current detection reference voltage source Vrefi, and two resistors forming an amplifier circuit. The two resistors and the operational amplifier 41 form an amplifier circuit that amplifies the voltage across both ends of the input current monitoring resistor 22 and outputs a voltage value IV1. The comparator 42 compares the voltage value IV1 output from the amplifier circuit with the current detection reference voltage Vrefi and in the case where Vrefi is exceeded, outputs an input current anomaly signal that turns the output on (logic value 1). The output form of the comparator 42 is an open-collector or open-drain configuration and the input current anomaly signal is input to the inverter of the control unit 32 and taken in by the control unit 32.

The control unit 32 performs processing to stop the direct-current regulator 11 when an anomaly occurs in accordance with the change in the logic value of the input current anomaly signal that is taken in and at the same time, outputs an anomaly alarm signal to the outside. The host circuit, such as an external CPU, recognizes the occurrence of an anomaly alarm by an interrupt etc. and determines the state of the direct-current regulator 11 from the status and issues a command to cut off the direct-current regulator 11 or to restart to the direct-current regulator 11. In a general direct-current regulator, the monitoring unit (measurement unit) and the circuits related to control and drive operate on the power source voltage, such as 5 V, 3 V, or 1 V, different from the input voltage and supplied to the normal logic circuit, etc.

Other monitoring units also have similar circuit configurations, but they do not relate to the embodiment directly, and therefore, explanation is omitted.

When a short circuit occurs due to the failure of the switching elements S1 and S2 or when the switching elements S1 and S2 enter the closed state due to the failure of the control circuit 32 in the direct-current regulator 11 illustrated in FIG. 1, a large current flows between the high potential side input voltage terminal (+(Vdd)) and the ground. At this time, when the monitoring unit (measurement circuit) inside the direct-current regulator 11 operates and an anomaly can be detected and the operation of the regulator can be stopped, there arises no problem in particular because the failure does not affect the external periphery.

However, in the case where a failure that leads to states (1) to (3) below has occurred, the operation to stop the direct-current regulator when an anomaly occurs is not performed, and therefore, the failure affects the peripheral circuits.

(1) In the case where the input voltage and the control circuit power source short-circuit within the gate driver 35 illustrated in FIG. 1 and the voltage for the monitoring circuit (measurement circuit) and the control unit 32 is lost.

(2) In the case where heat is produced rapidly at the time of the failure of the switching elements S1 and S2 and the failure of the control unit 32 is induced before the direct-current regulator starts the operation when an anomaly occurs and the operation is no longer possible.

(3) In the case where a failure occurs in the control unit 32 during the operation of the direct-current regulator and a drive signal that simultaneously brings the switching elements S1, S2 into the closed state is generated.

In the three cases above, the stop operation when an anomaly occurs is not performed and the state is brought about where the operation does not stop even if the stop operation is performed, and therefore, the failure affects the peripheral circuits, resulting in a serious failure.

Further, in a general direct-current regulator, as described above, the measurement circuit configured to measure the input/output voltage and current, the temperatures of the switching elements S1 and S2, etc., is incorporated, but the change in the characteristics of the switching element with the passage of time is not monitored. The switching element gradually deteriorates and breaks at a certain point of time, but the change in the characteristics with the passage of time is not monitored, and therefore, an anomaly is detected after the switching element enters the broken state as a result. If it is possible to detect the deterioration of the switching element in advance, it is possible to take measures against the occurrence of an anomaly before the switching element enters the broken state.

According to the embodiment, a direct-current regulator is implemented, which has the function to physically prevent a failure from affecting peripheral circuits when an anomaly occurs and at the same time, which detects the internal anomalous state and prevents the failure from affecting the peripheral circuits before an anomaly occurs by stopping the operation of the regulator in accordance with the detection of the anomaly.

Consequently, the direct-current regulator of the embodiment is of the synchronous rectification type and has the function to prevent a PCB and peripheral circuit elements from being broken (burned) when an overcurrent flows through the PCB and the peripheral circuit elements mounting the regulator due to the deterioration of an internal power conversion switching element.

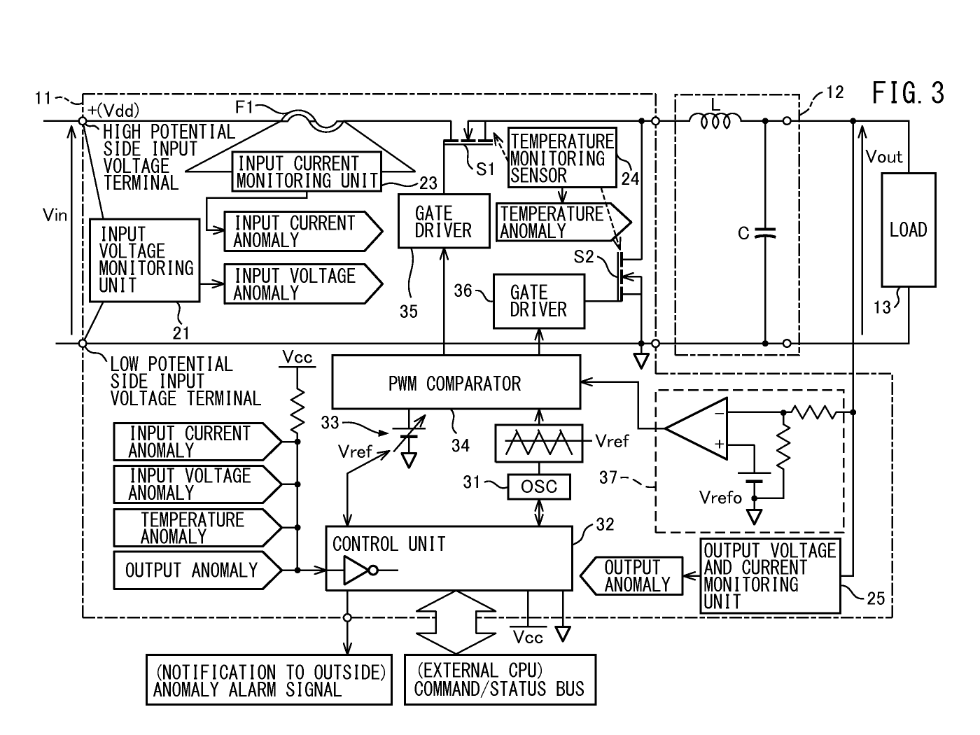

FIG. 3 is a diagram illustrating a configuration of the direct-current regulator of the embodiment and an electric circuit that uses the direct-current regulator.

The electric circuit has the direct-current regulator 11, the low-pass filter 12, and the load 13 as that illustrated in FIG. 1. The configuration and function of each unit are the same as those in FIG. 1, and therefore, explanation is omitted.

The direct-current regulator 11 has the high-side switch S1, the low-side switch S2, the oscillation circuit 31, the control circuit 32, the reference voltage source 33, the PWM comparator 34, the gate driver 35, the gate driver 36, and the error detection circuit 37. The direct-current regulator 11 further has the input voltage monitoring unit 21, the input current monitoring unit 23, the temperature monitoring sensor 24, the output voltage and current monitoring unit 25, and a fuse F1. As above, the direct-current regulator 11 of the embodiment differs from the direct-current regulator in FIG. 1 in that the fuse F1 is provided in place of the input current monitoring resistor 22. Further, as will be described later, the direct-current regulator 11 of the embodiment differs from the direct-current regulator in FIG. 1 in that the deterioration of the characteristics of the switching elements S1 and S2 is detected and other portions are the same. The fuse F1 cuts off the input current from the high potential side input terminal+(Vin) in the case where the input current of the direct-current regulator 11 is in the overcurrent state continuously.

First of all, the direct-current regulator 11 of the embodiment prevents the failure from affecting the peripheral circuits by detecting an anomalous state at an early stage and stopping the operation. However, as measures when an anomaly occurs in the control circuit, etc., but it is not possible to stop the operation of the direct-current regulator upon detection of the anomalous state, the electric fuse F1 is arranged inside the direct-current regulator to stop the operation and thus the failure is physically prevented from affecting the peripheral circuits. However, if the melting time of the fuse is long, the possibility that the failure affects the peripheral circuits before the fuse melts is raised, and therefore, it is desirable to reduce the melting time of the fuse. In the embodiment, the fuse F1 is used for input current monitoring.

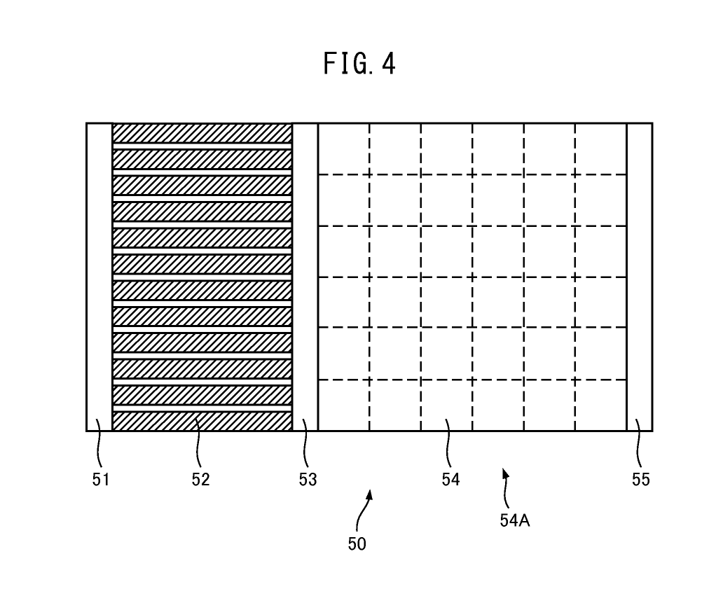

FIG. 4 is a diagram illustrating a configuration example of the fuse F1 and the high-side switch (switching element) S1.

As illustrated in FIG. 4, a silicon substrate 50 is divided into a first terminal part 51, a second terminal part 53, a third terminal part 55, a fuse element part between the first terminal part 51 and the second terminal part 53, and a switching element part 54A between the second terminal part 53 and the third terminal part 55. The first terminal part 51, the second terminal part 53, and the third terminal part 55 are electrodes formed on the silicon substrate 50. The first terminal part 51 and the second terminal part 53 are formed by, for example, polysilicon. In the fuse element part, a plurality of fuses 52 is formed in parallel so as to connect the first terminal part 51 and the second terminal part 53. The plurality of fuses 52 forms the fuse F1. The fuse 52 is a band of polysilicon formed between the first terminal part 51 and the second terminal part 53 and has a predetermined resistance value, and melts when a current equal to or more than a predetermined current value flows because of produced heat. It is desirable to form the band of the fuse 52 in the groove or to form the groove adjacent to the band of the fuse 52 and to provide a sealing material so as to form a space over the band of the fuse 52 and the groove so as to accommodate a molten fuse. Further, it may also be possible to form the band of the fuse 52 by the material of polysilicon in which phosphor particles are dispersed so that a desired resistance value can be obtained.

The switching element part 54A includes a plurality of transistor regions 54 and in each transistor region 54, a MOSFET is formed. In the plurality of formed MOSFETs, the drains are connected to the second terminal part 53, the sources are connected to the third terminal part 55, and the gates are connected in common and connected to the gate driver 35 through a path not illustrated schematically. The connection in this case is made by a via in accordance with necessity. Over the plurality of MOSFETs formed in the switching element part 54A and the wires, a protective film is formed and further, over the protective film, a sealing material is provided in common with the fuse element part.

The input current monitoring unit 23 detects an input current by detecting the voltage across the first terminal part 51 and the second terminal part 53.

The fuse F1 illustrated in FIG. 4 includes a plurality of band-shaped fuses 52 and the time taken by the fuse to melt is different for different band-shaped fuses, and therefore, it is considered that the time until the fuse F1 is cut off when all the band-shaped fuses 52 melt is lengthened. Consequently, it may also be possible to use the fuse F1 in a modified example as illustrated below.

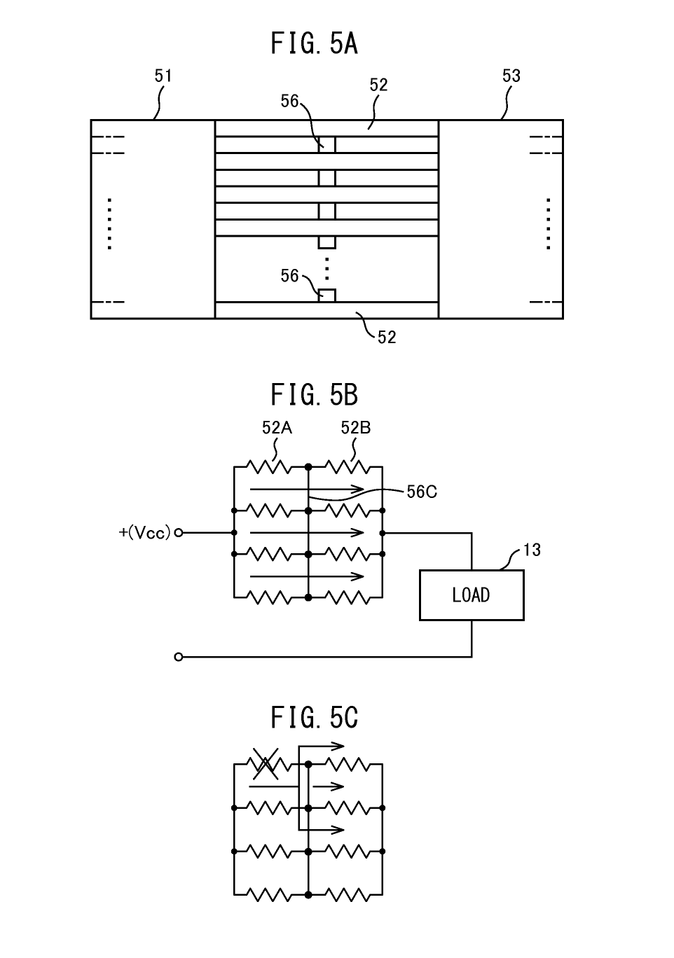

FIG. 5A to FIG. 5C are diagrams illustrating a modified example of the fuse F1: FIG. 5A illustrates a fuse pattern, FIG. 5B illustrates a circuit, and FIG. 5C is a diagram for explaining a reduction in the melting time.

As illustrated in FIG. 5A, in the fuse F1 in the modified example, a connection part 56 is provided, which connects the bands of the neighboring fuses 52 at intermediate parts thereof. The connection part 56 is formed, for example, by polysilicon on the silicon substrate 50 like the fuse 52.

It is possible to represent the fuse F1 in the modified example as described above as a form in which resistors are connected as illustrated in FIG. 5B. Resistors 52A and 52B represent the resistance components of the left side portion and the right side portion of the one fuse 52, a connection line 56C represents the resistance component of the connection part 56, and the connection part 56 is short and the resistance value is small, and therefore, it is represented as a wire.

As illustrated in FIG. 5C, if melting occurs at a portion of the resistance components, a large current flows through the neighboring resistance components, and therefore, the resistance components melt and a still larger current flows through the resistance components neighboring the resistance components, and thus, the molten portions spread rapidly. As described above, the fuse F1 in the modified example has a structure in which melting spreads easily to the neighboring portions from the portion at which melting occurs, and therefore, the melting time is reduced and the failure is prevented from affecting the peripheral circuits.

Further, depending on the use of the electric circuit that uses the direct-current regulator of the present embodiment, the magnitude of the load connected to the direct-current regulator differs and depending on the magnitude of the load, the input current of the regulator differs. Due to this, a direct-current regulator capable of accepting input currents in a wide range is demanded. Consequently, by making variable the current capacity dealt with by the fuse F1 of the direct-current regulator 11, it is possible to extend the application range of the direct-current regulator.

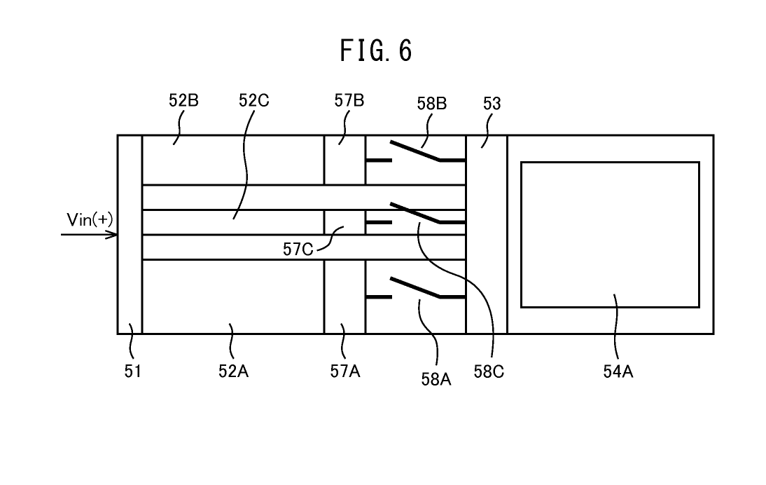

FIG. 6 is a diagram illustrating a modified example of the fuse F1 whose current capacity is made variable and the high-side switch (switching element) S1.

The fuse F1 and the switching element S1 in FIG. 6 are also formed on the silicon substrate and as in FIG. 4, have the first terminal part 51, the second terminal part 53, the switching element part 54A on the right side of the second terminal part 53, and the fuse element part between the first terminal part 51 and the second terminal part 53. The fuse element part in FIG. 6 has switch electrodes 57A to 57C provided at intermediate parts. The fuse element part has a plurality of band-shaped fuses 52A to 52C having different widths of the bands connecting the first terminal part 51 and the switch electrodes 57A to 57C, and a plurality of fuse connection switches 58A to 58C connecting the switch electrodes 57A to 57C and the second terminal part 53. The plurality of band-shaped fuses 52A to 52C is formed by the same method as that of the band-shaped fuse 52 in FIG. 4 and the band widths are different, and therefore, the current capacities are different and, for example, the current capacities are set in a ratio of 4:2:1. The plurality of fuse connection switches 58A to 58C is formed in the same manner as that of the MOSFET switch formed in the switching element part 54A. Over the plurality of MOSFETs and wires forming the switching element part 54A and the plurality of fuse connection switches 58A to 58C, a protective film is formed and further, over the protective film, a sealing material is provided so as to cover the protective film, including the plurality of band-shaped fuses 52A to 52C.

It is possible to vary the current capacity of the fuse F1 in FIG. 6 by setting the turning on/off of the plurality of fuse connection switches 58A to 58C. For example, in the case where only the fuse connection switch 58C is turned on, the current capacity takes the minimum value, in the case where only the fuse connection switch 58B is turned on, the current capacity takes a value twice the minimum value, and in the case where only the switch 58A is turned on, the current capacity takes a value four times the minimum value. Consequently, it is possible to vary the current capacity of the fuse in seven steps. By using the fuse in the modified example illustrated in FIG. 6, it is possible to deal with input currents in a wide range.

Further, the fuse in the modified example illustrated in FIG. 6 has fuse connection switches separately from the high-side switch S1. By turning off the fuse connection switches by the anomalous state signal of the direct-current regulator and the anomalous current detection signal detected by the characteristics monitoring function of the switching element, it is possible to immediately shut off the input current of the direct-current regulator. Due to this, it is possible to more securely prevent the failure from affecting the peripheral circuits than in the case where only the fuse is used. However, in the case where it is not possible to stop the anomalous operation by the fuse connection switch, the operation of the regulator is stopped by the fuse.

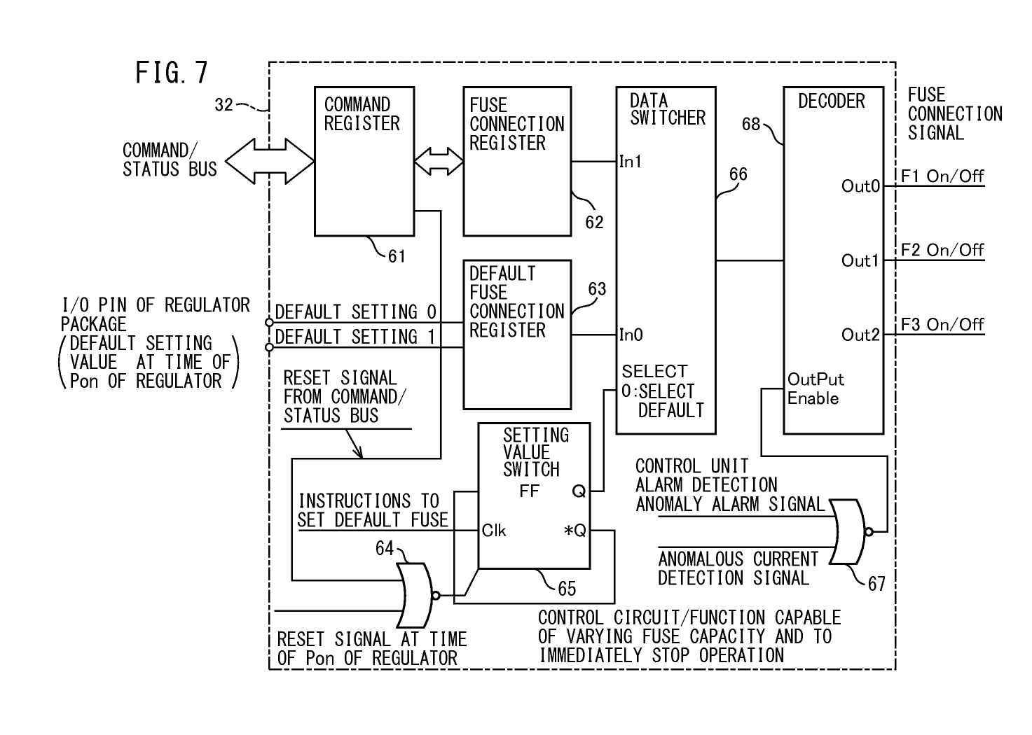

FIG. 7 is a diagram illustrating a configuration of a control portion that performs the function capable of varying the fuse capacity and the function to immediately stop the operation to be provided within the control circuit 32.

This control portion has a command register 61, a fuse connection register 62, a default fuse connection register 63, a NOR gate 64, a setting value switch and hold circuit (FF) 65, a data switcher 66, a NOR gate 67, and a decoder 68.

The command register 61 receives a command of the fuse setting value from an external CPU, etc., via a command/status bus and outputs a setting reset signal while performing the setting operation as well as outputting a setting value to the fuse connection register 62. The fuse connection register 62 receives and holds the fuse setting value from the command register 61.

The default fuse connection register 63 stores the default value of the fuse setting value determined in advance in the state where the fuse setting value is not specified yet, such as at the time of activation of the direct-current regulator. The default value is set by the value of the pin corresponding to two bits (0 or 1 of the logic value) of the direct-current regulator package for default value setting.

The NOR gate 64 receives the reset signal when the power of the direct-current regulator is turned on (Pon) and the reset signal from the command register 61. The NOR gate 64 resets the setting value switch and hold circuit (FF) 65 when one of the reset signals is active and brings the FF 65 into the set state when both reset signals are inactive.

The setting value switch and hold circuit (FF) 65 changes so as to output a selection signal “0” at the time of the reset and to output a selection signal “1” when fuse setting instructions, which are input from the outside, are input after the setting.

The data switcher 66 receives the fuse setting value from the command register 61 and the default fuse setting value from the default fuse connection register 63. The data switcher 66 selects and holds the default setting value when the selection signal is “0” and holds the fuse setting value received by the command register 61 when the selection signal is “1”.

Normally, the NOR gate 67 brings (enables) the decoder 68 into the operation state, but when the control unit, to be described later, generates an anomaly alarm signal or an anomalous current detection signal generated in the alarm detection processing, the NOR gate 67 outputs a signal to bring the decoder 68 into the non-operation state.

The decoder 67 decodes the setting value output from the data switcher 66 or the default setting value and controls the turning on/off of the fuse connection switches 58A to 58C.

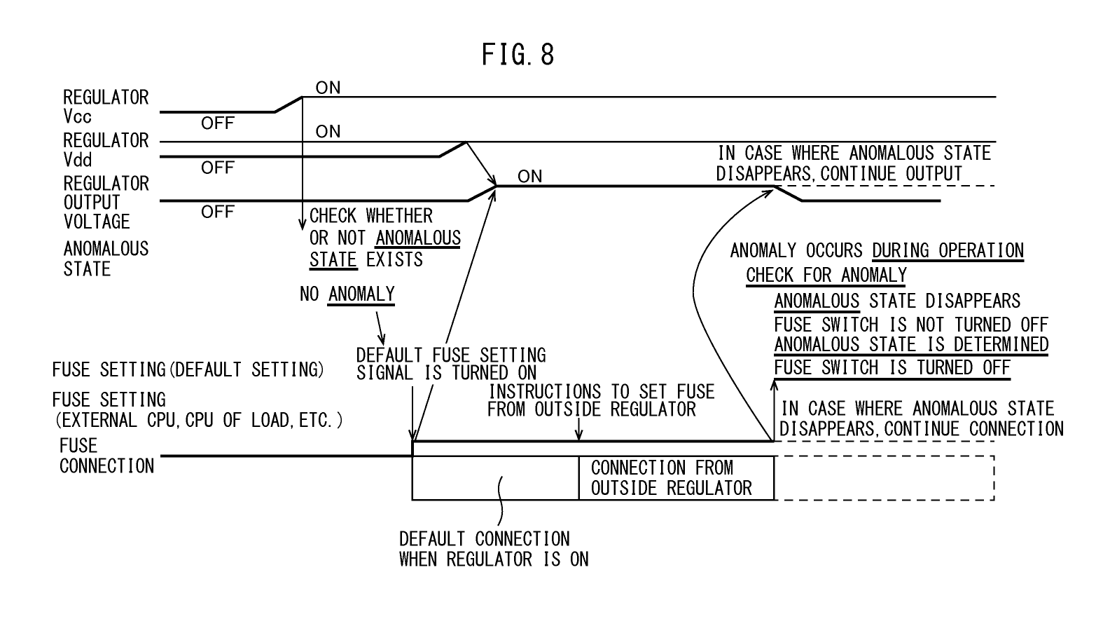

FIG. 8 is a time chart illustrating the operation of the fuse F1 by the control portion in FIG. 7.

When the power is turned on, a power source voltage Vcc of the whole including the regulator is input and the control circuit 2 enters the state capable of operation, the control portion in FIG. 7 also enters the operation state, and a Pon reset signal of the direct-current regulator is supplied. In this state, whether the state is anomalous is checked and if there is no anomaly, the reset signal is supplied via the command/status bus. In response to this, the data switcher 66 outputs the default setting value and the fuse connection switches 58A to 58C are set to the default connection state. In response to this, an input voltage Vdd of the direct-current regulator 11 rises and then an output voltage Vout also rises. After that, via the command/status bus, the setting value of the fuse is transmitted and when the instructions to set the fuse are input from the outside, the fuse connection switches 58A to 58C are set to the state in accordance with the setting value and the state is maintained.

After that, whether an anomaly has occurred is monitored during the operation and if an anomaly is recognized and the anomalous state is determined, the switches set in the connection state of the fuse connection switches 58A to 58C are turned off. In this case, the output voltage Vout of the direct-current regulator drops to the value in the off state (normally, 0 V). In the case where an anomaly is recognized, but it is observed that the anomalous state has disappeared after that, the fuse connection switches 58A to 58C are returned to the set connection state. In this case, Vout returns to the voltage in the on state.

The direct-current regulator of the embodiment further monitors the deterioration of the characteristics of the MOSFET used in the switching element. The characteristics of the MOSFET used in the switching element may sometimes deteriorate with the passage of time depending on the operation environment or due to the defect in the process of the MOSFET. If the change in the absolute resistance of the MOSFET is monitored inside the direct-current regulator, it is possible to detect and determine how the characteristics of the MOSFET have deteriorated, and therefore, it is possible to prevent a failure so serious that the fuse melts from occurring by stopping the operation of the direct-current regulator.

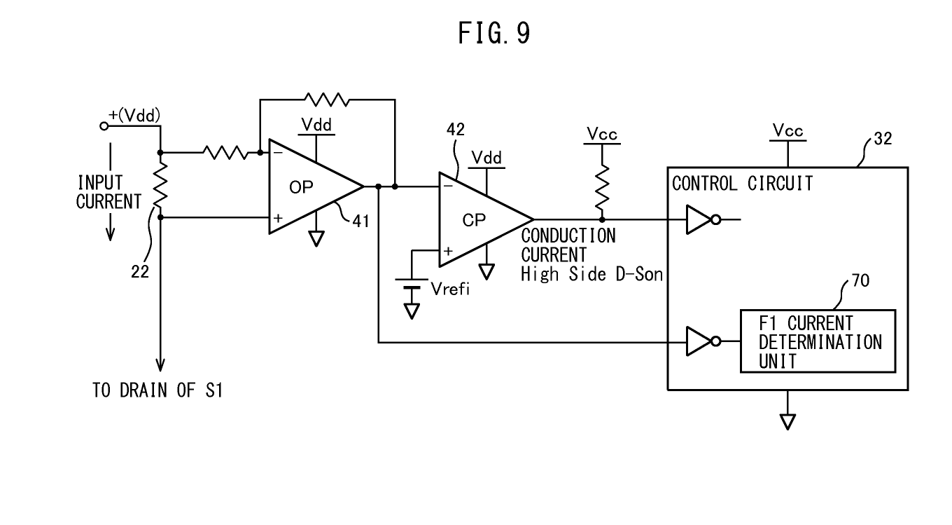

FIG. 9 is a diagram illustrating a circuit configuration of a portion for monitoring an input current in the direct-current regulator of the embodiment.

The control circuit 32 of the direct-current regulator of the embodiment has the configuration similar to that of the circuit in FIG. 2, but differs from the circuit in FIG. 2 in that how the characteristics of the MOSFET have deteriorated is detected and determined, in addition to the monitoring of the input voltage and current, the monitoring of the temperatures of S1 and S2, and the monitoring of the output voltage/current.

As illustrated in FIG. 9, the control circuit 32 of the direct-current regulator of the embodiment receives a voltage signal corresponding to the input current output from the operational amplifier 41. The control circuit 32 has an F1 current determination unit 70 configured to determine an anomaly from the signal indicating the input current flowing through the F1.

The F1 current determination unit 70 determines insulating properties of S1 and S2 and the penetrating current from the input current when a predetermined drive signal is applied to the gates of S1 and S2.

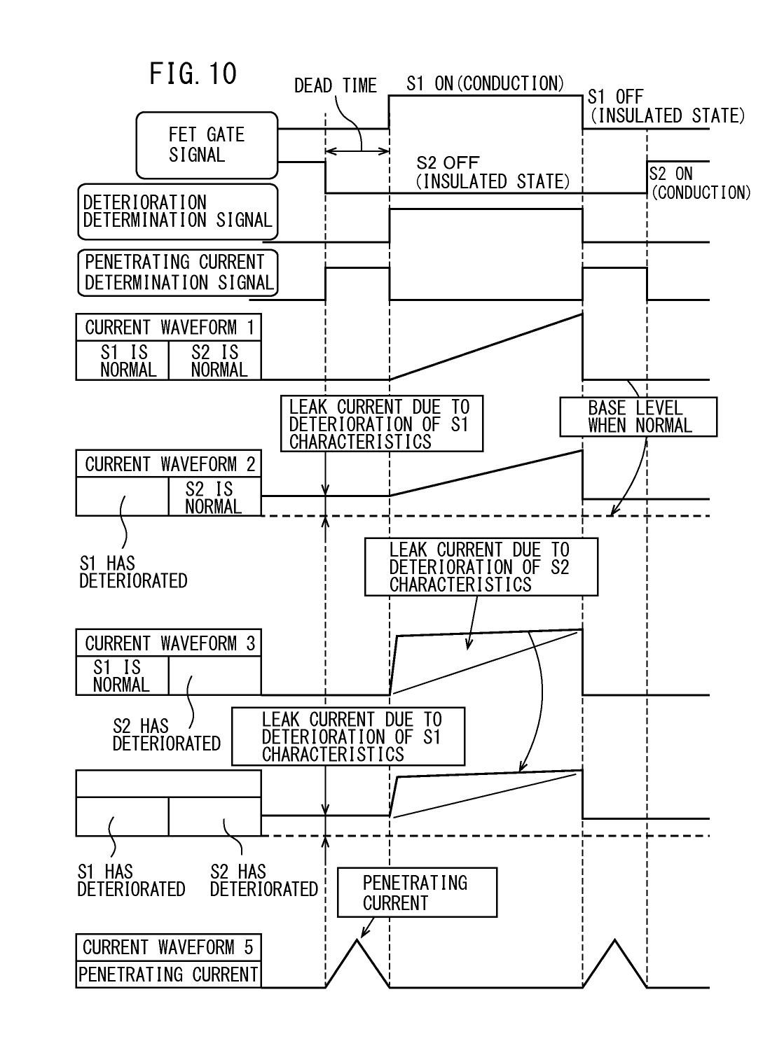

FIG. 10 is a diagram illustrating the above-described determination operation in the F1 current determination unit 70.

To the gates of S1 and S2, a gate signal illustrated schematically is applied. S1 and S2 alternately turn on and off so that both do not enter the on state (conduction state) at the same time. Consequently, after S2 enters the off state (insulated state), S1 enters the on state and remains in the on state for a predetermined period of time. Then, after S1 enters the off state, S2 enters the on state. Here, the time from when S2 enters the off state to when S1 enters the on state is referred to as a dead time.

The F1 current determination unit 70 takes the current flowing from the input terminal to S1 (plus current) to be a deterioration determination signal and the current in the opposite direction, i.e., flowing from S1 to the input terminal (minus current) to be a penetrating current determination signal and manages both currents.

A current waveform 1 indicates the change in the deterioration determination signal in accordance with the change in the gate signal in the case where S1 and S2 are normal. The current during the dead time during which S1 and S2 are off is zero and when S1 turns on, the current increases and when S1 turns off, the current becomes zero.

A current waveform 2 indicates the change in the deterioration determination signal in the case where S1 has deteriorated into the state where insulation is not achieved even if S1 turns off and S2 is normal. A current flows also during the dead time because S1 does not achieve perfect insulation. If this current becomes large, it is determined that S1 has deteriorated.

A current waveform 3 indicates the change in the deterioration determination signal in the case where S2 has deteriorated into the state where insulation is not achieved even if S2 turns off and S1 is normal. In the state where S2 is off and S1 is on, the current increases as in the current waveform 1 in the normal state, but in this case, the current is increased by the amount corresponding to the leaked current of S2, and therefore, the value of the current is large from the beginning as illustrated schematically. Consequently, in the case where the current when a short time elapses after S1 turns on is larger than the current in the current waveform 1 by a certain amount or more, it is determined that S1 has deteriorated.

A current waveform 4 indicates the case where both S1 and S2 have deteriorated and the waveform is a combination of the waveforms 2 and 3.

A current waveform 5 indicates the penetrating current determination signal. In the normal state, a current never flows in the backward direction, i.e., from S1 to the input terminal and the penetrating current determination signal is zero. However, if an anomaly occurs, in which the voltage (output voltage) Vout at the output terminal of the direct-current regulator becomes larger than the voltage (input voltage) Vdd at the input terminal due to some causes, a backflow of the current occurs through a parasitic diode of S1 and the penetrating current determination signal is no longer zero. Consequently, if the penetrating current determination signal becomes equal to or more than a predetermined value during the dead time during which S1 is off, it is determined that the state is anomalous.

The above is the anomalous current monitoring processing that uses the fuse F1 in the control circuit.

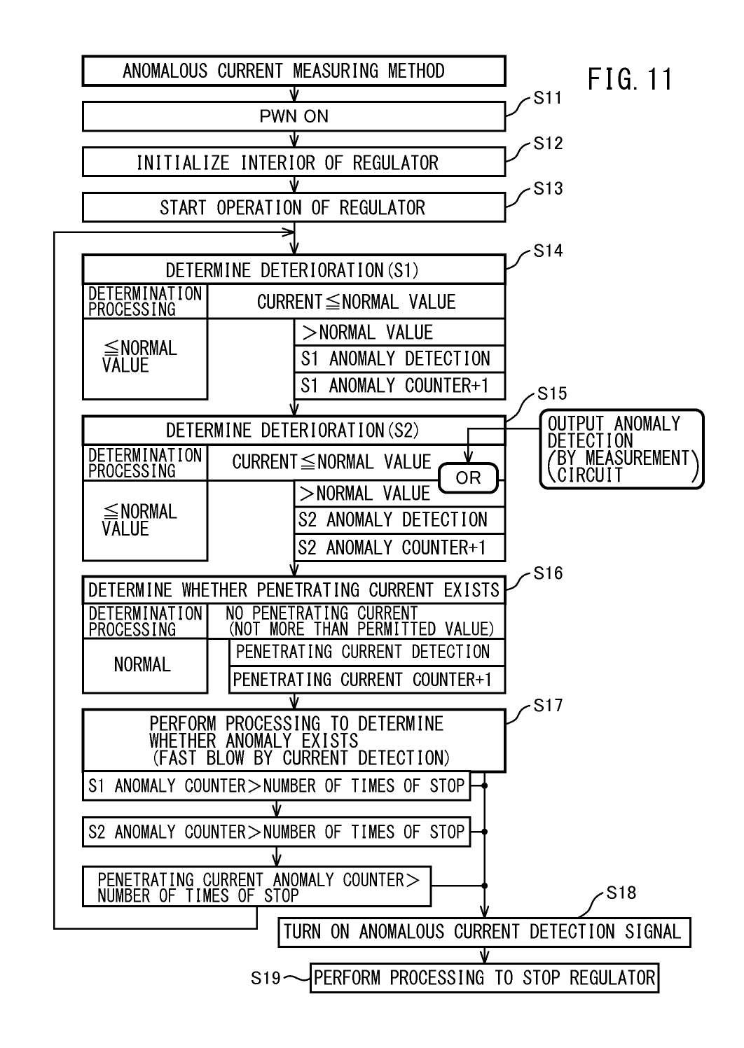

FIG. 11 is a flowchart illustrating the anomalous current monitoring processing in the control circuit.

At step S11, power is turned on (power on).

At step S12, the interior of the direct-current regulator is initialized as explained in FIG. 8.

At step S13, the operation of the direct-current regulator is started as explained in FIG. 8.

At step S14, deterioration of S1 is determined. In this determination, if the deterioration determination signal during the dead time is equal to or less than the normal value, S1 is determined to be normal and if it is larger than the normal value, S1 is determined to be anomalous. In the case where S1 is determined to be anomalous, a counter of the number of times of S1 anomaly is incremented by 1 and in the case where S1 determined to be normal, the counter of the number of times of S1 anomaly is cleared.

At step S15, deterioration of S2 is determined. In this determination, if the deterioration determination signal when a predetermined time elapses after S1 turns on in FIG. 10 is equal to or less than the normal value, S2 is determined to be normal and if it is larger than the normal value, S2 is determined to be anomalous. In the case where S2 is determined to be anomalous, a counter of the number of times of S2 anomaly is incremented by 1 and in the case where S2 is determined to be normal, the counter of the number of times of S2 anomaly is cleared.

At step S16, whether or not the penetrating current exists is determined. In this determination, if the penetrating current determination signal during the dead time is equal to or less than a permitted value (absolute value is equal to or less than a predetermined value), it is determined that the state is normal and if it is larger than the permitted value, it is determined that the state is anomalous. In the case where the state is determined to be anomalous, a counter of number of times of penetrating current anomaly is incremented by 1 and in the case where the state is determined to be normal, the counter of the number of times of penetrating current anomaly is cleared.

At step S17, whether the count value of one of the counter of the number of times of S1 anomaly, the counter of the number of times of S2 anomaly, and the counter of the number of times of penetrating current anomaly described above exceeds a number of times of stop. In the case where the number of times of stop is exceeded, the procedure proceeds to step S18 and in the case where the number of times of stop is not exceeded, the procedure returns to step S14.

At step S18, the anomalous current detection signal is turned on.

At step S19, the control unit 32 performs the regulator stop processing previously described.

According to the direct-current regulator of the embodiment explained above and the electric circuit that uses the regulator, the effects as follows are obtained.

(1) Because a fuse is provided, even if the control circuit within the direct-current regulator does not work, it is possible to shut off an unexpected large current and to prevent the failure from affecting the periphery.

(2) When an anomaly occurs in the regulator, it is possible to immediately stop the operation of the direct-current regulator by turning on the anomaly detection signal to turn off the fuse connection switch, and therefore, it is possible to prevent the failure from affecting the periphery.

(3) It is no longer necessary to separately provide the current shut-off function, such as a fuse, on the PCB for the direct-current regulator, and therefore, it is possible to reduce the number of parts to be mounted on the PCB and to make an attempt to reduce the failure rate. Further, in the case where an external fuse is provided on the PCB, the characteristics of the fuse material deteriorate with the passage of use time depending on the use environment (temperature, contents in the atmosphere), and therefore, a failure occurs, such as the power source of the PCB or the device cannot be turned off or turned on. In contrast to this, in the direct-current regulator of the embodiment, the fuse is provided within the direct-current regulator element, and therefore, it is possible to give the characteristics that are not readily affected by the use environment.

(4) The accuracy of the fail analysis (FA) of a power conversion element (switching element) is improved and it is made possible to analyze the state of deterioration of an element. By shutting off the overcurrent at the time of the occurrence of a failure, it is made possible to obtain a sample in the early stage of the failure, and therefore, it is possible to improve the analysis accuracy of a failed portion. Due to this, it is possible to determine whether the failure is caused by the insufficient performance of the direct-current regulator itself or by the error in the circuit conditions on the side on which the direct-current regulator is used, and therefore, it is possible to clearly select the method for addressing the failure.

As explained above, according to the embodiment, a direct-current regulator is implemented, which predicts the occurrence of an anomaly by detecting deterioration of the switching element as well as preventing a failure from affecting the peripheral circuits in the case where an anomaly occurs.

All examples and conditional language provided herein are intended for pedagogical purposes of aiding the reader in understanding the invention and the concepts contributed by the inventor to further the art, and are not to be construed as limitations to such specifically recited examples and conditions, nor does the organization of such examples in the specification relate to a illustrating of the superiority and inferiority of the invention. Although one or more embodiments of the present invention have been described in detail, it should be understood that the various changes, substitutions, and alterations could be made hereto without departing from the spirit and scope of the invention.

What is claimed is:

1. A direct-current regulator comprising:
a fuse, a high-side switch, and a low-side switch connected in series between a high potential side input voltage terminal and a low potential side input voltage terminal; and
a control unit configured to control the high-side switch and the low-side switch, wherein
the fuse is formed on a silicon substrate on which the high-side switch is formed.

2. The direct-current regulator according to claim 1, wherein
the fuse includes: two electrodes separately formed on the silicon substrate; and a plurality of band-shaped polysilicon films formed between the two electrodes.

3. The direct-current regulator according to claim 2, wherein
the fuse includes a linking part of a polysilicon film provided so as to connect the neighboring band-shaped polysilicon films at intermediate portions.

4. The direct-current regulator according to claim 2, wherein
the fuse includes:
first and second electrodes separately formed on the silicon substrate;
a plurality of relay electrodes separately formed at intermediate portions of the first and second electrodes;
a plurality of band-shaped polysilicon films formed respectively between the first electrode and the plurality of relay electrodes; and
a plurality of switching elements formed respectively between the plurality of relay electrodes and the second electrode, and
the control unit controls the connections of the plurality of switching elements, and the current capacity of the fuse is different in accordance with the connection state of the plurality of switching elements.

5. The direct-current regulator according to claim 1, wherein
the control unit controls the high-side switch and the low-side switch so that both the switches are not brought into conduction simultaneously but are brought into conduction alternately, and
the control unit determines that the high-side switch has deteriorated when an input current, which is detected at a time of controlling the high-side switch and the low-side switch so as to be brought out of conduction, exceeds a normal value.

6. The direct-current regulator according to claim 1, wherein
the control unit controls the high-side switch and the low-side switch so that both the switches are not brought into conduction simultaneously but are brought into conduction alternately, and
the control unit determines that the low-side switch has deteriorated when an input current, which is detected after bringing the high-side switch into conduction in a state where the low-side switch is brought out of conduction, exceeds a normal value.

7. The direct-current regulator according to claim 1, wherein
the control unit controls the high-side switch and the low-side switch so that both the switches are not brought into conduction simultaneously but are brought into conduction alternately, and
the control unit determines that the direct-current regulator is anomalous when a current flowing from the high-side switch to the high potential side input voltage terminal, which is detected when controlling the high-side switch and the low-side switch so as to be brought out of conduction, exceeds a normal value.

8. A DC-DC converter comprising:
a regulator including: a fuse, a high-side switch, and a low-side switch connected in series between a high potential side input voltage terminal and a low potential side input voltage terminal, the fuse being formed on a silicon substrate on which the high-side switch is formed; and a control unit configured to control the high-side switch and the low-side switch; and
a low-pass filter connected between a connection node of a high-side switch and a low-side switch and a low potential side input voltage terminal.

9. An anomaly monitoring method of a direct-current regulator, the direct-current regulator including: a fuse, a high-side switch, and a low-side switch connected in series between a high potential side input voltage terminal and a low potential side input voltage terminal, the fuse being formed on a silicon substrate on which the high-side switch is formed; and a control unit configured to control the high-side switch and the low-side switch, the method comprising:
controlling the high-side switch and the low-side switch so that both the switches are not brought into conduction simultaneously but brought into conduction alternately; and
detecting an input current by using the fuse when controlling the high-side switch and the low-side switch so as to be brought out of conduction, and determining that the high-side switch has deteriorated when the detected input current exceeds a normal value.

10. An anomaly monitoring method of a direct-current regulator, the direct-current regulator including: a fuse, a high-side switch, and a low-side switch connected in series between a high potential side input voltage terminal and a low potential side input voltage terminal, the fuse being formed on a silicon substrate on which the high-side switch is formed; and a control unit configured to control the high-side switch and the low-side switch, the method comprising:
controlling the high-side switch and the low-side switch so that both the switches are not brought into conduction simultaneously but brought into conduction alternately; and
detecting an input current by using the fuse after bringing the high-side switch into conduction in the state where the low-side switch is brought out of conduction, and determining that the low-side switch has deteriorated when the detected input current exceeds a normal value.
